(19) United States
(12) Patent Application Publication
(10) Pub. No.: US 2019/0287868 A1
(43) Pub. Date: Sep. 19, 2019

(54) EXPOSING CIRCUITRY FOR DIE TESTING

(71) Applicant: Intel Corporation, Santa Clara, CA (US)

(72) Inventor: Michael Zelikson, Haifa (IL)

(73) Assignee: Intel Corporation, Santa Clara, CA (US)

(21) Appl. No.: 15/921,931

(22) Filed: Mar. 15, 2018

(51) Int. Cl. H01L 21/66; H01L 23/50; H01L 23/528; H01L 25/065; H01L 23/00; H01L 23/48; H01L 25/00

(52) U.S. Cl. CPC H01L 22/34; H01L 2224/05025; H01L 23/5286; H01L 22/30; H01L 25/0657; H01L 24/05; H01L 24/17; H01L 23/481; H01L 25/50; H01L 2225/06596; H01L 2225/06513; H01L 2224/06181; H01L 2224/17181; H01L 2225/06517; H01L 2224/16146; H01L 23/50

(57) ABSTRACT

Disclosed herein are structures and techniques for exposing circuitry in die testing. For example, in some embodiments, an integrated circuit (IC) die may include: first conductive contacts at a first face of the die; second conductive contacts at a second face of the die, wherein the second face is opposite to the first face; circuitry; and a switch coupled between the second conductive contacts and the circuitry, wherein the circuitry is not electrically exposed by the second conductive contacts when the switch is open, and the circuitry is electrically exposed by the second conductive contacts when the switch is closed.

### BACKGROUND

Integrated circuit (IC) dies may be tested as a part of the manufacturing process. Such tests may include mechanical tests and circuitry performance tests.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIGS. 1 and 2 are side, cross-sectional views of a die including a circuitry exposure switch, in accordance with various embodiments.

FIG. 3 is a side, cross-sectional view of an integrated circuit (IC) package including the die of FIG. 1, in accordance with various embodiments.

FIG. 4 is a side, cross-sectional view of the die stack in the IC package of FIG. 3, in accordance with various embodiments.

FIGS. 5A and 5B are side views of connections between different power delivery networks in a die when a circuitry exposure switch is opened and closed, respectively, in accordance with various embodiments.

FIG. 6 is a flow diagram of a method of testing an IC die, in accordance with various embodiments.

FIG. 7 is a top view of a wafer and dies that may include a circuitry exposure switch, in accordance with any of the embodiments disclosed herein.

FIG. 8 is a side, cross-sectional view of an IC device that may include a circuitry exposure switch, in accordance with any of the embodiments disclosed herein.

FIG. 9 is a side, cross-sectional view of an IC device assembly that may include a circuitry exposure switch, in accordance with any of the embodiments disclosed herein.

FIG. 10 is a block diagram of an example electrical device that may include a circuitry exposure switch, in accordance with any of the embodiments disclosed herein.

### DETAILED DESCRIPTION

Disclosed herein are structures and techniques for exposing circuitry in die testing. For example, in some embodiments, an integrated circuit (IC) die may include: first conductive contacts at a first face of the die; second conductive contacts at a second face of the die, wherein the second face is opposite to the first face; circuitry; and a switch coupled between the second conductive contacts and the circuitry, wherein the circuitry is not electrically exposed by the second conductive contacts when the switch is open, and the circuitry is electrically exposed by the second conductive contacts when the switch is closed.

Some IC structures, such as IC packages, may include multiple dies stacked on top of one another. In such structures, power may be delivered to an upper die through a lower die in a stack. When determining how to stack dies, it may be desirable to position a die that consumes more power (and therefore generate more heat) “higher up” in a stack relative to a die that consumes less power so that the heat of the power intensive die may be more readily dissipated (e.g., by a thermal management device). Further, conducting the power needed by the upper die through the lower die may involve the use of many of the die-to-die interconnects between the lower die and the upper die, as well as the thicker “top metal” of the lower die, in order to achieve a suitably low resistance power delivery network for the upper die. Others of the die-to-die interconnects between the lower die in the upper die may be used for signaling between the dies.

When some or all of the die-to-die interconnects between a lower die and an upper die are used for power delivery to the upper die or die-to-die signaling, there may be few or no conductive contacts available at the top surface of the lower die that may be used to test certain circuitry of the lower die. For example, the lower die may include its own power delivery network, but this power delivery network may not be exposed by the conductive contacts available at the top surface of the lower die. If it is desired to test the power delivery network of the lower die (e.g., during SORT or other testing as part of a high-volume manufacturing process), the power delivery network of the lower die may be inaccessible from the top surface of the lower die. Testing the power delivery network of the lower die from its bottom surface may not be feasible or possible (e.g., because not all power planes of the bottom die are exposed at its bottom surface, because the interconnects at the bottom surface of the lower die may be damaged during such testing, and/or because the signaling circuitry is not exposed at the bottom surface and it is desirable to perform all testing of the lower die at only one face).

The structures and techniques disclosed herein may allow circuitry that is otherwise “hidden” from conductive contacts at a face of a die to be exposed to those conductive contacts (and therefore testable) by selectively shorting such circuitry to those conductive contacts by a dedicated switch. Such a switch may be closed during testing, and opened during normal operation. Such structures and techniques may decouple testing needs from operational needs, allowing a die to be designed for its desired operation while still maintaining testability. For example, the structures and techniques disclosed herein may improve the performance of IC structures that include die stacks by allowing higher power delivery to upper dies in the stacks (and therefore higher performance) than achievable by die stacks limited by conventional testing requirements. Although the examples discussed above relate to the testing of power delivery networks in a lower die, these structures and techniques may be used to test any suitable “hidden” circuitry in a die, in accordance with any of the embodiments disclosed herein.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The drawings are not necessarily to scale. Although many of the drawings illustrate rectilinear structures with flat walls and right-angle corners, this is simply for ease of illustration, and actual devices made using these techniques will exhibit rounded corners, surface roughness, and other features.

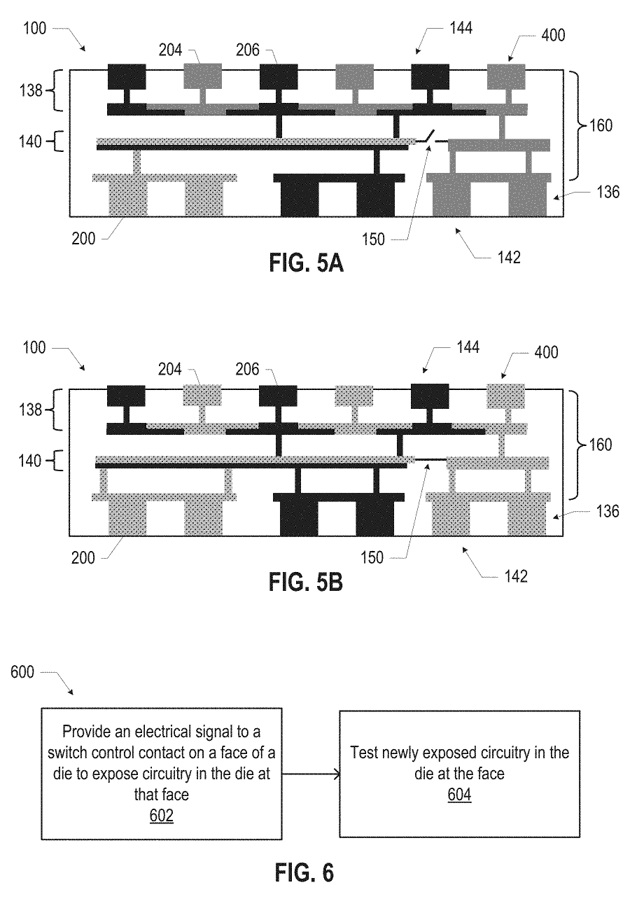

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, a “package” and an “IC package” are synonymous. As used herein, a “die” and an “IC die” are synonymous. When used to describe a range of dimensions, the phrase “between X and Y” represents a range that includes X and Y. For convenience, the phrase “FIG. 5” may be used to refer to the collection of drawings of FIGS. 5A-5B.

FIG. 1 is a side, cross-sectional view of a die 100 having a first face 142 and an opposing second face 144. Conductive contacts 124 may be disposed at the first face 142, and conductive contacts 400 may be disposed at the second face 144. As used herein, a “conductive contact” may refer to a portion of conductive material (e.g., metal) serving as an electrical interface between different components; conductive contacts may be recessed in, flush with, or extending away from a surface of a component, and may take any suitable form (e.g., a conductive pad or socket). The die 100 may have conductive pathways between the first face 142 and the second face 144, or between different locations on the first face 142, and/or between different locations on the second face 144. These conductive pathways may take the form of any of the interconnects 1628 discussed below with reference to FIG. 8. In some embodiments, the pitch and/or the size of the conductive contacts 124 may be different than the pitch and/or size, respectively, of the conductive contacts 400. For example, in some embodiments, the conductive contacts 124 may interface with first-level interconnects to electrically couple the conductive contacts 124 to conductive contacts of a package substrate, and the conductive contacts 400 may interface with die-to-die interconnects to electrically couple the conductive contacts 400 to another die (e.g., as discussed below with reference to FIGS. 3 and 4). In some other embodiments, the conductive contacts 124 may interface with a first set of die-to-die interconnects to electrically couple the conductive contacts 124 to conductive contacts of another die, and the conductive contacts 400 may interface with die-to-die interconnects to electrically couple the conductive contacts 402 different die (e.g., when the die 100 is between two other dies in a die stack). The die 100 may be used in other arrangements (e.g., an interposer may be coupled to the conductive contacts 124 or the conductive contacts 400, etc.).

The die 100 may include multiple sets of circuitry. For example, FIG. 1 illustrates an embodiment in which the die 100 includes at least three sets of circuitry: circuitry 200, circuitry 204, and circuitry 300. Some of the sets of circuitry in the die 100 may be exposed at the second face 144 of the die 100, and some of the sets of the circuitry in the die 100 may not be exposed at the second face 144 of the die 100. As used herein, a set of circuitry is “exposed” at a face of a die when the operation of that circuitry may be tested by a testing device (e.g., a probe card) in electrical contact with conductive contacts at the face of the die. In the embodiment of FIG. 1, the circuitry 204 and circuitry 300 may be exposed at the second face of the die 100, while the circuitry 200 may not be exposed at the second face of the die 100. Circuitry in the die 100 that is exposed when a circuitry exposure switch 150 (discussed below) is open may be referred to herein as “exposed circuitry” and circuitry in the die 100 that is not exposed when the circuitry exposure switch 150 is open may be referred to herein as “hidden circuitry.” Note that whether a set of circuitry is “exposed” or “hidden” depends upon the particular face 142 or 144 that is being used as a reference; circuitry that is “exposed” or “hidden” with reference to the first face 142 may be “exposed” or “hidden” with reference to the second face 144. For ease of discussion, when discussing which circuitry of the die 100 is “exposed” or “hidden” herein, the reference face of the die 100 will be the second face 144; in other embodiments, the reference face may be the first face 142.

In some embodiments, different sets of circuitry in the die 100 may be power delivery circuitry or signal circuitry. Power delivery circuitry may provide a positive supply voltage, ground, and/or a negative supply voltage. Signal circuitry may perform signal processing, communications, computing, or other operations. In some embodiments, some power delivery circuitry included in the die 100 may be used to provide a power delivery network for signal circuitry in the die 100, while other power delivery circuitry included in the die 100 may be part of a power delivery network for another die (not shown) that may be coupled to the die 100. For example, as discussed below with reference to FIGS. 3-5, the exposed circuitry 300 may be signal circuitry, the hidden circuitry 200 may be a power delivery network for the circuitry 300, and the exposed circuitry 204 may be part of a power delivery network for a die (not shown in FIG. 1) that is to be electrically coupled to the conductive contacts 400 at the second face 144 of the die 100.

Although FIG. 1 illustrates the hidden circuitry 200 as not including any of the conductive contacts 400 at the second face 144 of the die 100, this need not be the case. Hidden circuitry, such as the hidden circuitry 200, may include electrical pathways to one or more conductive contacts 400 at the second face 144, but these electrical pathways may not be adequate to test the operation of that circuitry. Additionally, although FIG. 1 depicts the different sets of circuitry 200, 204, and 300 as mutually exclusive, this is simply for ease of illustration, and need not be the case. In some embodiments, a hidden set of circuitry may share some electrical pathways with an exposed set of circuitry. For example, when the circuitry 200 is a power delivery network and the circuitry 204 is a power delivery network, the circuitry 200 and the circuitry 204 may share ground pathways (e.g., ground planes).

The die 100 may include a circuitry exposure switch 150. The circuitry exposure switch 150 may be coupled between hidden circuitry and other circuitry (hidden or exposed) so that, when the circuitry exposure switch 150 is closed, the hidden circuitry is exposed. For example, in the embodiment illustrated in FIG. 1, a circuitry exposure switch 150 is coupled between the exposed circuitry 204 and the hidden circuitry 200; when the circuitry exposure switch 150 is closed, the hidden circuitry 200 may be exposed (i.e., the operation of the circuitry 200 may be tested by a testing device in electrical contact with conductive contacts 400 at the second face 144 of the die 100). The state of the circuitry exposure switch 150 (i.e., closed or opened) may be controlled by electrical signals provided to a switch control contact 410 at the second face 144 of the die 100. The switch control contact 410 may be one of the conductive contacts 400. During testing of the die 100, the testing device may contact appropriate ones of the conductive contacts 400, and may provide an appropriate electrical signal (e.g., a positive supply voltage) to the switch control contact 410 to cause the circuitry exposure switch 150 to close and thereby expose the hidden circuitry 200 for testing. When the die 100 is not being tested, an appropriate electrical signal (e.g., ground) may be provided to the switch control contact 410 (e.g., by a die or another component electrically coupled to the conductive contacts 400 at the second face 144, as discussed below with reference to FIGS. 3-4) to keep the circuitry exposure switch 150 open.

Although a single circuitry exposure switch 150 is depicted in FIG. 1 (and others of the accompanying figures), and the singular term “circuitry exposure switch 150” is used herein, this is simply for ease of discussion, and a die 100 may include multiple circuitry exposure switches 150 arranged appropriately so that, when the circuitry exposure switches 150 are closed, the hidden circuitry is exposed. In some embodiments, the circuitry exposure switches 150 may be provided by a dedicated mesh of embedded power gates. In some embodiments, a single switch control contact 410 may be in electrical contact with multiple circuitry exposure switches 150 to cause the multiple circuitry exposure switches 150 to open/close.

A die 100 may include one or more switch control contacts 410. In some embodiments, each switch control contact 410 may be associated with a different set of circuitry exposure switches 150; providing an appropriate electrical signal to a switch control contact 410 may control the behavior of the associated set of circuitry exposure switches 150. A single circuitry exposure switch 150 may be included in multiple different sets of circuitry exposure switches 150 (associated with multiple different switch control contacts 410. More generally, a die 100 may include multiple switch control contacts 410 that may have different logical functionalities (individually and/or in combination with each other) to control the behavior of different sets of circuitry exposure switches 150 in the die 100. For example, a first set of circuitry exposure switches 150 may be associated with a low voltage applied to each of two different switch control contacts 410, a second set of circuitry exposure switches 150 may be associated with a high voltage applied to each of the two different switch control contacts 410, a third set of circuitry exposure switches 150 may be associated with a low voltage applied to one of the switch control contacts 410 and a high voltage applied to the other of the switch control contacts 410, etc.

Any suitable circuit architecture may provide the circuitry exposure switch 150. For example, in some embodiments, the circuitry exposure switch 150 may include a slow start (“soft start”) power gate whose power-up time constant may be selected to mitigate any high current spikes that may damage the die 100 or the testing device. In some embodiments, the circuitry exposure switch 150 may include buffers to support the distribution of control signals from the switch control contact 410 to some or all of the circuitry exposure switches 150.

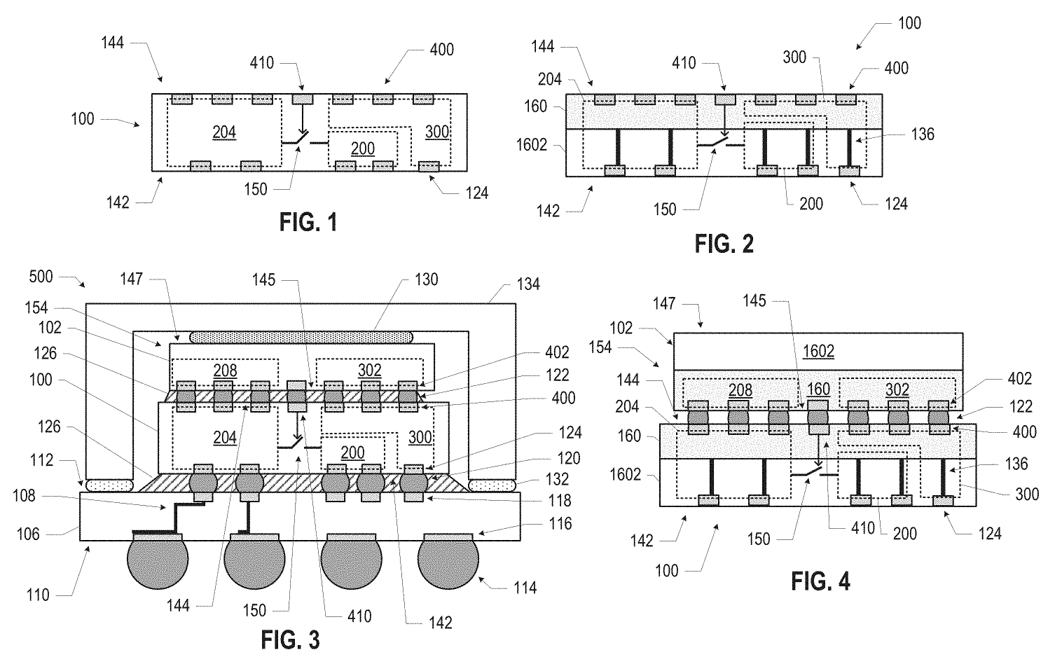

The die 100 may have any suitable structure. For example, FIG. 2 illustrates an embodiment of the die 100 of FIG. 1 in which the die 100 includes an active region 160 proximate to the second face 144 and a substrate 1602 proximate to the first face 142. Conductive contacts 124 at the first face 142 may be electrically coupled to the active region 160 (e.g., at the device layer 1604 or in the metallization stack 1619, as discussed below with reference to FIG. 8) by through-silicon vias 136 through the substrate 1602. Although the term “through-silicon via 136” is used to refer to conductive pathways through the substrate 1602, this is simply a term of art, and the substrate 1602 may be formed of materials other than silicon. Embodiments of the active region 160 and the substrate 1602 are discussed below with reference to FIGS. 5 and 8. In the embodiment of FIG. 2, the circuitry exposure switch 150 is depicted as located proximate to the through-silicon vias 136, but this is simply for ease of illustration, and the circuitry of the circuitry exposure switch 150 may be distributed in any desired manner through the die 100.

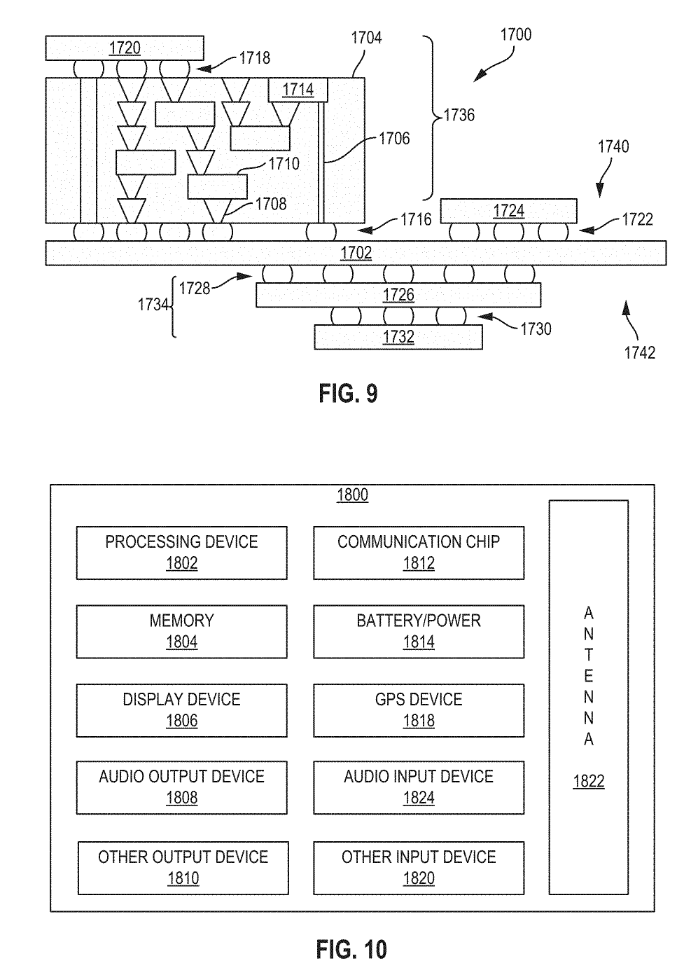

As noted above, in some embodiments, the die 100 may be part of a larger assembly. For example, FIG. 3 is a side, cross-sectional view of an IC package 500 including the die 100 of FIG. 1. In the IC package 500, the conductive contacts 124 at the first face 142 of the die 100 are coupled to conductive contacts 118 at the second face 112 of the package substrate 106 by first-level interconnects 120. Second-level interconnects 114 may be coupled to conductive contacts 116 at the first face 110 of the package substrate 106. The package substrate 106 may be formed of a dielectric material, and may have conductive pathways 108 extending through the dielectric material between the first face 110 and the second face 112, or between different locations on the first face 110, and/or between different locations on the second face 112. The conductive contacts 118 may be coupled to conductive pathways 108 through the package substrate 106, allowing circuitry within the die 100 and/or the die 102 to electrically couple to various ones of the conductive contacts 116. The first-level interconnects 120 illustrated in FIG. 3 are solder bumps (e.g., controlled collapse chip connection (“C4”) bumps), but any suitable first-level interconnects 120 may be used. The second-level interconnects 114 illustrated in FIG. 3 are solder balls (e.g., for a ball grid array arrangement), but any suitable second-level interconnects 114 may be used (e.g., pins in a pin grid array arrangement or lands in a land grid array arrangement). The second-level interconnects 114 may be used to couple the IC package 500 to another component, such as a circuit board (e.g., a motherboard), an interposer, a socket (e.g., on a motherboard), or another IC package, as known in the art and as discussed below with reference to FIG. 9.

A die 102 may be coupled to the second face 144 of the die 100. In particular, conductive contacts 400 at the second face 144 of the die 100 may be electrically coupled to conductive contacts 402 at a first face 145 of the die 102 by die-to-die interconnects 122 (e.g., micro-C4 bumps). The switch control contact 410 at the second face 144 of the die 100 may be electrically coupled to a conductive contact 402 at the first face 145 of the die 102; the die 102 may provide a suitable electrical signal (e.g., ground) to the switch control contact 410 to cause the circuitry exposure switch 150 to remain open. The die 100 and the die 102 may together provide a die stack 154. In some embodiments, an underfill material 126 may be disposed around the first-level interconnects 120 and/or the die-to-die interconnects 122. Example materials that may be used for the underfill material 126 may include epoxy materials.

A thermal management device 134 may be disposed around the die stack 154. The thermal management device 134 may include a heat spreader or heat sink, and may make thermal contact with the die 102 via a thermal interface material 130 at a second face 147 of the die 102. In some embodiments, a sealant 132 may couple the foot of the thermal management device 134 to the second face 112 of the package substrate 106. In some embodiments, an overmold material (not shown) may be disposed around the die stack 154 instead of or in addition to a thermal management device 134. Other thermal management structures may be included in the IC package 500; for example, heat pipes may be included in the die 100 and/or the die 102.

In FIG. 3, the die 102 is shown as including circuitry 208 and circuitry 302. In some embodiments, the 302 may be signal circuitry, and the circuitry 208 may be part of a power delivery network for the circuitry 302. In particular, in some embodiments, the power delivery network for the circuitry 302 may be provided by the circuitry 208 in conjunction with the circuitry 204 of the die 100; the circuitry 204 and the circuitry 208 may together deliver power from the package substrate 106 to the circuitry 302. In some embodiments, the die 102 may generate more heat during operation than the die 100. In some embodiments, the die 102 may include one or more processing cores.

The die stack 154 may have any suitable structure. For example, FIG. 4 illustrates an embodiment of the die stack 154 of FIG. 3 including the die 100 of FIG. 2 and an embodiment of the die 102 in which the die 102 includes an active region 160 proximate to the first face 145 and a substrate 1602 proximate to the second face 147. Thus, the dies 100 and 102 may be arranged “face-to-face” in that their active regions 160 face each other. In other embodiments, the dies 100 and 102 may not be arranged in a face-to-face arrangement (e.g., the dies 100 and 102 may be arranged in a “face-to-back side” arrangement). The circuitry 208 and 302 of the die 102 may be included in the active region 160.

Although the die stacks 154 depicted in FIGS. 3 and 4 include two dies, this is simply for ease of illustration, and the die stacks 154 may include more than two dies, as desired. In a die stack 154 that includes more than two dies, the die 100 may be any of the dies other than the “top” die; for example, the die 100 may be any die located between two other dies, or between a die and the package substrate 106.

Although the IC package 500 illustrated in FIG. 3 is a flip chip package, other package architectures may be used. For example, the IC package 500 may be a ball grid array (BGA) package, such as an embedded wafer-level ball grid array (eWLB) package. In another example, the IC package 500 may be a wafer-level chip scale package (WLCSP) or a panel fanout (FO) package. An IC package 500 may include additional passive components, such as surface-mount resistors, capacitors, and inductors disposed on the first face 110 or the second face 112 of the package substrate 106. More generally, an IC package 500 may include any other active or passive components known in the art. The IC package 500 may include any suitable dies including any suitable devices. For example, the IC package 500 may include processing and/or communication circuitry for a mobile device. In another example, the IC package 500 may include processing and/or communication circuitry for a server.

FIG. 5 illustrates an embodiment of the die 100 in which the hidden circuitry 200 includes a positive supply voltage network for the die 100 (part of a power delivery network for the die 100), the exposed circuitry 204 includes a positive supply voltage network for the die 102 (part of a power delivery network for the die 102, not shown), and the die 100 further includes a ground network 206 shared by the power delivery networks of the die 100 and the die 102. The hidden circuitry 200 is shown with dotted shading, the exposed circuitry 204 is shown with gray shading, and the ground network 206 is shown with black shading. In FIG. 5, the active region 160 includes top metal layers 138 and routing metal layers 140. The top metal layers 138 may be thicker (and thus less resistive) than the routing metal layers 140. In some embodiments, portions (not shown) of the top metal layers 138 may support a decoupling solution; for example, portions of the top metal layers 138 may be used for metal-insulator-metal capacitors. In some embodiments, some of these metal-insulator-metal capacitors (not shown) may be part of the hidden circuitry 200 (the power delivery network of the die 100), and some of these metal-insulator-metal capacitors may be part of the exposed circuitry 204 (the power delivery network of the die 102). The routing metal layers 140 may be between the top metal layers 138 and the through-silicon vias 136. In FIG. 5, no signal circuitry is shown for ease of illustration (but may be present). Further, FIG. 5 does not depict a switch control contact 410 for ease of illustration. Because the top metal layers 138 may be thicker (and therefore less resistive) than the routing metal layers 140, and because the die 102 may consume more power than the die 100, it may be advantageous to use a large percentage of the top metal layers 138 of the die 100 for the exposed circuitry 204 (the positive supply voltage network for the die 102) in order to achieve improved power delivery to the die 102.

FIG. 5A illustrates a configuration in which a circuitry exposure switch 150 of the die 100 is open, and FIG. 5B illustrates a configuration which the circuitry exposure switch 150 of the die 100 is closed. In FIG. 5A, the hidden circuitry 200 is not exposed by the conductive contacts 400 at the second face 144 of the die 100; in particular, all of the conductive contacts 400 depicted in FIG. 5A are part of the exposed circuitry 204 or the ground network 206.

FIG. 5B illustrates a configuration which the circuitry exposure switch 150 of the die 100 is closed (e.g., upon provision of an appropriate electrical signal to a switch control contact 410, not shown). Closing the circuitry exposure switch 150 may “short” the exposed circuitry 204 and the hidden circuitry 200 so that the hidden circuitry 200 is exposed at the second face 144 (i.e., the operation of the circuitry 200 may be tested by a testing device in electrical contact with conductive contacts 400 at the second face 144 of the die 100). When testing is complete, the circuitry exposure switch 150 may be opened again.

FIG. 6 is a flow diagram of a method 600 of testing an IC die, in accordance with various embodiments. Although the operations of the method 600 may be illustrated with reference to particular embodiments of the dies 100 disclosed herein, the method 600 may be used to as part of a manufacturing and testing process of any suitable die. Operations are illustrated once each and in a particular order in FIG. 6, but the operations may be reordered and/or repeated as desired (e.g., with different operations performed in parallel when testing multiple electronic components simultaneously).

At 602, an electrical signal may be provided to a switch control contact on a face of a die to expose circuitry in the die at that face. For example, an electrical signal may be provided to a switch control contact 410 on the second face 144 of a die 100 (e.g., by a testing device) to cause a circuitry exposure switch 150 to close, shorting conductive contacts at the second face of the die 100 to the hidden circuitry 200 and thereby exposing the hidden circuitry 200 in the die 100 at the second face 144.

At 604, the newly exposed circuitry in the die may be tested at the face. For example, the hidden circuitry 200 (exposed by the closing of the circuitry exposure switch 150) may be tested by a probe card or other testing device making electrical contact with conductive contacts at the second face 144 of the die 100.

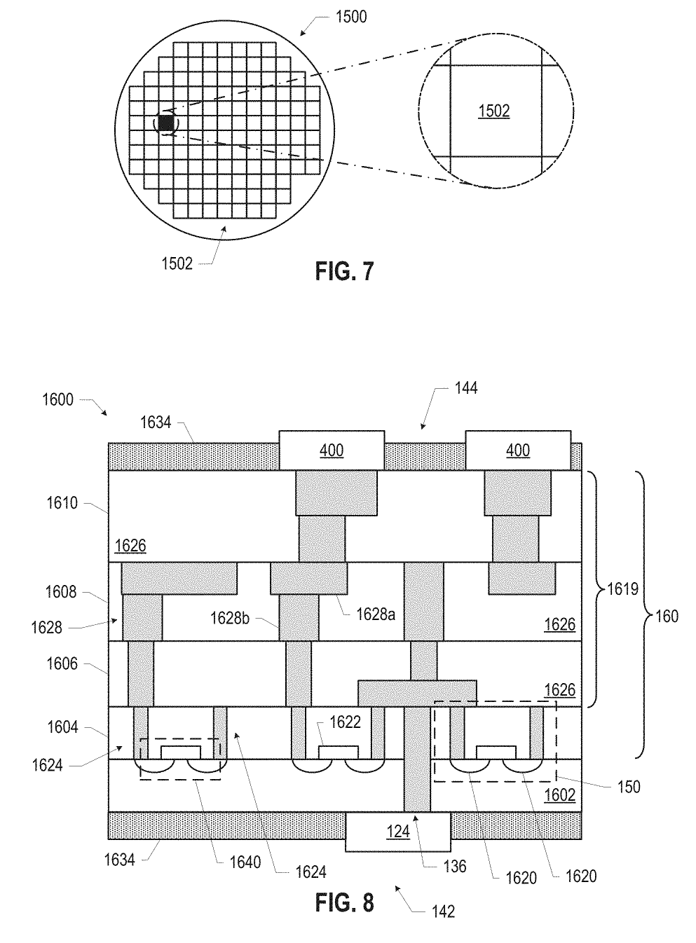

The circuitry exposure switches 150 and related arrangements disclosed herein may be included in any suitable electronic structure. FIGS. 7-10 illustrate various examples of IC structures that may include any of the circuitry exposure switches 150 and related arrangements disclosed herein.

FIG. 7 is a top view of a wafer 1500 and dies 1502 that may include one or more circuitry exposure switches 150 or related arrangements, in accordance with any of the embodiments disclosed herein. For example, the dies 1502 may be the dies 100 or the dies 102 discussed above. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more circuitry exposure switches 150 or related arrangements (a single circuitry exposure switch 150 is depicted in FIG. 7 for illustrative purposes), one or more transistors (e.g., some of the transistors 1640 of FIG. 8, discussed below) and/or supporting circuitry to route electrical signals to the transistors, as well as any other IC components. In some embodiments, the wafer 1500 or the die 1502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 10) or other logic that is configured to store information in the memory devices or execute instructions stored in the memory array.

FIG. 8 is a side, cross-sectional view of an IC device 1600 that may include one or more circuitry exposure switches 150 or related arrangements, in accordance with any of the embodiments disclosed herein. One or more of the IC devices 1600 may be included in one or more dies 1502 (FIG. 7). The IC device 1600 may be formed on a substrate 1602 (e.g., the wafer 1500 of FIG. 7) and may be included in a die (e.g., the die 1502 of FIG. 7). The substrate 1602 may be a semiconductor substrate composed of semiconductor material systems including, for example, n-type or p-type materials systems (or a combination of both). The substrate 1602 may include, for example, a crystalline substrate formed using a bulk silicon or a silicon-on-insulator (SOI) substructure. In some embodiments, the substrate 1602 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the substrate 1602. Although a few examples of materials from which the substrate 1602 may be formed are described here, any material that may serve as a foundation for an IC device 1600 may be used. The substrate 1602 may be part of a singulated die (e.g., the dies 1502 of FIG. 7) or a wafer (e.g., the wafer 1500 of FIG. 7). As shown in FIG. 8, through-silicon vias 136 may extend through the substrate 1602, and may contact the metallization stack 1619 at any suitable interconnect layer (discussed below). Conductive contacts 124 may be disposed at the first face 142 of the IC device 1600, and may be electrically coupled to the through-silicon vias 136.

The IC device 1600 may include one or more device layers 1604 disposed on the substrate 1602. The device layer 1604 may include features of one or more transistors 1640 (e.g., metal oxide semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 8 and may include a wide variety of other types and configurations such as, for example, planar transistors, non-planar transistors, or a combination of both. Planar transistors may include bipolar junction transistors (BJT), heterojunction bipolar transistors (HBT), or high-electron-mobility transistors (HEMT). Non-planar transistors may include FinFET transistors, such as double-gate transistors or tri-gate transistors, and wrap-around or all-around gate transistors, such as nanoribbon and nanowire transistors. Other devices, such as memristors, may be included in an IC device 1600.

Each transistor 1640 may include a gate 1622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1640 along the source-channel-drain direction, the gate electrode may consist of a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1620 may be formed within the substrate 1602 adjacent to the gate 1622 of each transistor 1640. The S/D regions 1620 may be formed using an implantation/diffusion process or an etching/deposition process, for example. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion-implantation process. In the latter process, the substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620.

Electrical signals, such as power and/or input/output (I/O) signals, may be routed to and/or from the devices (e.g., transistors 1640) of the device layer 1604 through one or more interconnect layers disposed on the device layer 1604 (illustrated in FIG. 8 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form a metallization stack (also referred to as an “ILD stack”) 1619 of the IC device 1600.

In some embodiments, one or more circuitry exposure switches 150 may be disposed in the device layer 1604, in accordance with any of the techniques disclosed herein. In particular, a circuitry exposure switch 150 may include one or more transistors 1640. FIG. 8 illustrates a single circuitry exposure switch 150 in the device layer 1604 for illustration purposes, but any number and structure of circuitry exposure switches 150 may be included in the device layer 1604). More generally, the circuit components that may be included in a circuitry exposure switch 150 may be distributed at any suitable locations in the IC device 1600. One or more circuitry exposure switches 150 may be coupled to any suitable ones of the devices in the device layer 1604, and/or to one or more of the conductive contacts 400 (discussed below).

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 8). Although a particular number of interconnect layers 1606-1610 is depicted in FIG. 8, embodiments of the present disclosure include IC devices having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the substrate 1602 upon which the device layer 1604 is formed. For example, the lines 1628a may route electrical signals in a direction in and out of the page from the perspective of FIG. 8. The vias 1628b may be arranged to route electrical signals in a direction of a plane that is substantially perpendicular to the surface of the substrate 1602 upon which the device layer 1604 is formed. In some embodiments, the vias 1628b may electrically couple lines 1628a of different interconnect layers 1606-1610 together.

The interconnect layers 1606-1610 may include a dielectric material 1626 disposed between the interconnect structures 1628, as shown in FIG. 8. In some embodiments, the dielectric material 1626 disposed between the interconnect structures 1628 in different ones of the interconnect layers 1606-1610 may have different compositions; in other embodiments, the composition of the dielectric material 1626 between different interconnect layers 1606-1610 may be the same.

A first interconnect layer 1606 may be formed directly on the device layer 1604. In some embodiments, the first interconnect layer 1606 may include lines 1628a and/or vias 1628b, as shown. The lines 1628a of the first interconnect layer 1606 may be coupled with contacts (e.g., the S/D contacts 1624) of the device layer 1604. In some embodiments, the first interconnect layer 1606 may be part of the routing metal 140 (FIG. 5). More generally, the routing metal 140 may include one or more interconnect layers at the “bottom” of the metallization stack 1619.

A second interconnect layer 1608 may be formed above the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual-damascene process) in some embodiments.

A third interconnect layer 1610 (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device layer 1604) may be thicker. In some embodiments, the third interconnect layer 1610 may be part of the top metal 138 (FIG. 5). More generally, the top metal 138 may include one or more interconnect layers at the “top” of the metallization stack 1619.

The IC device 1600 may include a solder resist material 1634 (e.g., polyimide or similar material) and one or more conductive contacts 400 formed on the interconnect layers 1606-1610 at the second face 144. In FIG. 8, the conductive contacts 400 (and the conductive contacts 124) are illustrated as taking the form of bond pads. The conductive contacts 400 and the conductive contacts 124 may be electrically coupled with the interconnect structures 1628 and configured to route the electrical signals of the transistor(s) 1640 and/or other components included in the IC device 1600 to other external devices. For example, solder bonds may be formed on the one or more conductive contacts 400 and 124 to mechanically and/or electrically couple a chip including the IC device 1600 with other components (e.g., a die or another circuit board). The IC device 1600 may include additional or alternate structures to route the electrical signals from the interconnect layers 1606-1610; for example, the conductive contacts 400 and 124 may include other analogous features (e.g., posts) that route the electrical signals to external components.

FIG. 9 is a side, cross-sectional view of an IC device assembly 1700 that may include one or more IC packages or other electronic components (e.g., a die) including one or more circuitry exposure switches 150 or related arrangements, in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 500 discussed above with reference to FIG. 1 (e.g., may include one or more circuitry exposure switches 150 in a die 100).

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 9 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 9), male and female portions of a socket, an adhesive, an underfill material, and/or any other suitable electrical and/or mechanical coupling structure.

The package-on-interposer structure 1736 may include an IC package 1720 coupled to an interposer 1704 by coupling components 1718. The coupling components 1718 may take any suitable form for the application, such as the forms discussed above with reference to the coupling components 1716. Although a single IC package 1720 is shown in FIG. 9, multiple IC packages may be coupled to the interposer 1704; indeed, additional interposers may be coupled to the interposer 1704. The interposer 1704 may provide an intervening substrate used to bridge the circuit board 1702 and the IC package 1720. The IC package 1720 may be or include, for example, a die (the die 1502 of FIG. 7), an IC device (e.g., the IC device 1600 of FIG. 8), or any other suitable component. Generally, the interposer 1704 may spread a connection to a wider pitch or reroute a connection to a different connection. For example, the interposer 1704 may couple the IC package 1720 (e.g., a die) to a set of BGA conductive contacts of the coupling components 1716 for coupling to the circuit board 1702. In the embodiment illustrated in FIG. 9, the IC package 1720 and the circuit board 1702 are attached to opposing sides of the interposer 1704; in other embodiments, the IC package 1720 and the circuit board 1702 may be attached to a same side of the interposer 1704. In some embodiments, three or more components may be interconnected by way of the interposer 1704.

In some embodiments, the interposer 1704 may be formed as a PCB, including multiple metal layers separated from one another by layers of dielectric material and interconnected by electrically conductive vias. In some embodiments, the interposer 1704 may be formed of an epoxy resin, a fiberglass-reinforced epoxy resin, an epoxy resin with inorganic fillers, a ceramic material, or a polymer material such as polyimide. In some embodiments, the interposer 1704 may be formed of alternate rigid or flexible materials that may include the same materials described above for use in a semiconductor substrate, such as silicon, germanium, and other group III-V and group IV materials. The interposer 1704 may include metal interconnects 1708 and vias 1710, including but not limited to through-silicon vias 1706. The interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1704. The package-on-interposer structure 1736 may take the form of any of the package-on-interposer structures known in the art. In some embodiments, an interposer 1704 may include one or more circuitry exposure switches 150 (and related circuitry), in accordance with any of the embodiments disclosed herein, to enable testing of the interposer 1704 during the manufacturing and design process.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 9 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 10 is a block diagram of an example electrical device 1800 that may include one or more circuitry exposure switches 150, in accordance with any of the embodiments disclosed herein. For example, any suitable ones of the components of the electrical device 1800 may include one or more of the IC packages 500, IC devices 1600, or dies 100 or 1502 disclosed herein. A number of components are illustrated in FIG. 10 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 10, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 is an integrated circuit (IC) structure, including: a die, including: first conductive contacts at a first face of the die, second conductive contacts at a second face of the die, wherein the second face is opposite to the first face, circuitry, and a switch coupled between the second conductive contacts and the circuitry, wherein the circuitry is not electrically exposed by the second conductive contacts when the switch is in a first state, and the circuitry is electrically exposed by the second conductive contacts when the switch is in a second state different from the first state.

Example 2 may include the subject matter of Example 1, and may further specify that the second conductive contacts include a switch control contact to which electrical signals may be applied to change a state of the switch.

Example 3 may include the subject matter of Example 2, and may further specify that the switch is one of a plurality of switches, and electrical signals may be applied to the switch control contact to change states of the plurality of switches.

Example 4 may include the subject matter of Example 3, and may further specify that the switch control contact is a single switch control contact.

Example 5 may include the subject matter of any of Examples 1-4, and may further specify that the circuitry is a power delivery network for the die.

Example 6 may include the subject matter of Example 5, and may further specify that the power delivery network is to provide power for signal circuitry of the die.

Example 7 may include the subject matter of any of Examples 1-6, and may further specify that the die is a first die and the IC structure further includes: a second die including conductive contacts at a first face of the second die; wherein the conductive contacts at the first face of the second die are electrically coupled to the second conductive contacts at the second face of the first die.

Example 8 may include the subject matter of Example 7, and may further specify that the conductive contacts at the first face of the second die are electrically coupled to the second conductive contacts at the second face of the first die by solder.

Example 9 may include the subject matter of any of Examples 7-8, and may further specify that: the circuitry is a first power delivery network for the first die; the first die further includes a first portion of a second power delivery network for the second die; and the second die further includes a second portion of the second power delivery network for the second die.

Example 10 may include the subject matter of Example 9, and may further specify that the switch is coupled between the first portion of the second power delivery network and the first power delivery network.

Example 11 may include the subject matter of Example 9, and may further specify that the second power delivery network is to provide power for signal circuitry of the second die.

Example 12 may include the subject matter of any of Examples 1-11, and may further include: a package substrate, including: first conductive contacts at a first face of the package substrate, and second conductive contacts at a second face of the package substrate, wherein the second face of the package substrate is opposite to the first face of the package substrate; wherein the second conductive contacts at the second face of the package substrate are electrically coupled to the first conductive contacts at the first face of the die.

Example 13 may include the subject matter of Example 12, and may further include: solder on the first conductive contacts at the first face of the package substrate.

Example 14 may include the subject matter of any of Examples 1-13, and may further specify that the die includes through-silicon vias.

Example 15 may include the subject matter of any of Examples 1-14, and may further specify that the first state of the switch is an open state and the second state of the switch is a closed state.

Example 16 is a method of manufacturing an integrated circuit (IC) structure, including: providing an electrical signal to a switch control contact on a face of a die to change a state of a switch in the die to expose circuitry in the die to conductive contacts at the face of the die; and testing the exposed circuitry.

Example 17 may include the subject matter of Example 16, and may further specify that the circuitry is a power delivery network of the die.

Example 18 may include the subject matter of any of Examples 16-17, and may further specify that the conductive contacts are first conductive contacts, the face of the die is a first face of the die, the die further includes second conductive contacts at a second face of the die, and the second face is opposite to the first face.

Example 19 may include the subject matter of Example 18, and may further include: coupling conductive contacts of a second die to the first conductive contacts of the first die.

Example 20 may include the subject matter of Example 19, and may further specify that: the circuitry is a first power delivery network for the first die; the first die further includes a first portion of a second power delivery network for the second die; the second die further includes a second power of the second power delivery network for the second die; and the switch is coupled between the first portion of the second power delivery network and the first power delivery network.

Example 21 is an integrated circuit (IC) package, including: a first die, including: conductive contacts at a face of the first die, circuitry, and a switch coupled between the conductive contacts and the circuitry, wherein the circuitry is not electrically exposed by the conductive contacts when the switch is in a first state, and the circuitry is electrically exposed by the conductive contacts when the switch is in a second state; and a second die, including:

conductive contacts at a face of the second die, wherein the conductive contacts of the second die are electrically coupled to the conductive contacts of the first die.

Example 22 may include the subject matter of Example 21, and may further specify that the circuitry is a first power delivery network for the first die; the first die further includes a first portion of a second power delivery network for the second die; and the second die further includes a second power of the second power delivery network for the second die.

Example 23 may include the subject matter of Example 22, and may further specify that the switch is coupled between the first portion of the second power delivery network and the first power delivery network.

Example 24 may include the subject matter of any of Examples 21-23, and may further include: a thermal management device in thermal contact with the second die.

Example 25 may include the subject matter of any of Examples 21-24, and may further include: a package substrate; wherein the conductive contacts at the face of the first die are first conductive contacts, the face of the first die is a first face, the first die further includes second conductive contacts at a second face of the first die, the second face of the first die is opposite to the first face of the first die; and the second conductive contacts at the second face of the first die are coupled to conductive contacts at a face of the package substrate.

Example 26 may include the subject matter of any of Examples 21-25, and may further specify that the second die includes a processing core.

Example 27 may include the subject matter of any of Examples 21-26, and may further specify that the first state of the switch is an open state and the second state of the switch is a closed state.

1. An integrated circuit (IC) structure, comprising:
a die, including:
first conductive contacts at a first face of the die,
second conductive contacts at a second face of the die, wherein the second face is opposite to the first face,
circuitry, and
a switch coupled between the second conductive contacts and the circuitry, wherein the circuitry is not electrically exposed by the second conductive contacts when the switch is in a first state, and the circuitry is electrically exposed by the second conductive contacts when the switch is in a second state different from the first state.

2. The IC structure of claim 1, wherein the second conductive contacts include a switch control contact to which electrical signals may be applied to change a state of the switch.

3. The IC structure of claim 2, wherein the switch is one of a plurality of switches, and electrical signals may be applied to the switch control contact to change states of the plurality of switches.

4. The IC structure of claim 3, wherein the switch control contact is a single switch control contact.

5. The IC structure of claim 1, wherein the circuitry is a power delivery network for the die.

6. The IC structure of claim 5, wherein the power delivery network is to provide power for signal circuitry of the die.

7. The IC structure of claim 1, wherein the die is a first die and the IC structure further includes:
a second die including conductive contacts at a first face of the second die;
wherein the conductive contacts at the first face of the second die are electrically coupled to the second conductive contacts at the second face of the first die.

8. The IC structure of claim 7, wherein the conductive contacts at the first face of the second die are electrically coupled to the second conductive contacts at the second face of the first die by solder.

9. The IC structure of claim 7, wherein:
the circuitry is a first power delivery network for the first die;
the first die further includes a first portion of a second power delivery network for the second die; and
the second die further includes a second portion of the second power delivery network for the second die.

10. The IC structure of claim 9, wherein the switch is coupled between the first portion of the second power delivery network and the first power delivery network.

11. The IC structure of claim 9, wherein the second power delivery network is to provide power for signal circuitry of the second die.

12. The IC structure of claim 1, further comprising:
a package substrate, including:
first conductive contacts at a first face of the package substrate, and
second conductive contacts at a second face of the package substrate, wherein the second face of the package substrate is opposite to the first face of the package substrate;
wherein the second conductive contacts at the second face of the package substrate are electrically coupled to the first conductive contacts at the first face of the die.

13. The IC structure of claim 12, further comprising:
solder on the first conductive contacts at the first face of the package substrate.

14. The IC structure of claim 1, wherein the die includes through-silicon vias.

15. The IC structure of claim 1, wherein the first state of the switch is an open state and the second state of the switch is a closed state.

16. A method of manufacturing an integrated circuit (IC) structure, comprising:
providing an electrical signal to a switch control contact on a face of a die to change a state of a switch in the die to expose circuitry in the die to conductive contacts at the face of the die; and
testing the exposed circuitry.

17. The method of claim 16, wherein the circuitry is a power delivery network of the die.

18. The method of claim 16, wherein the conductive contacts are first conductive contacts, the face of the die is a first face of the die, the die further includes second conductive contacts at a second face of the die, and the second face is opposite to the first face.

19. The method of claim 18, further comprising:
coupling conductive contacts of a second die to the first conductive contacts of the first die.

20. The method of claim 19, wherein:
the circuitry is a first power delivery network for the first die;
the first die further includes a first portion of a second power delivery network for the second die;
the second die further includes a second power of the second power delivery network for the second die; and
the switch is coupled between the first portion of the second power delivery network and the first power delivery network.

21. An integrated circuit (IC) package, comprising:
a first die, including:
conductive contacts at a face of the first die,
circuitry, and
a switch coupled between the conductive contacts and the circuitry, wherein the circuitry is not electrically exposed by the conductive contacts when the switch is in a first state, and the circuitry is electrically exposed by the conductive contacts when the switch is in a second state; and
a second die, including:
conductive contacts at a face of the second die, wherein the conductive contacts of the second die are electrically coupled to the conductive contacts of the first die.

22. The IC package of claim 21, wherein the circuitry is a first power delivery network for the first die;
the first die further includes a first portion of a second power delivery network for the second die; and
the second die further includes a second power of the second power delivery network for the second die.

23. The IC package of claim 22, wherein the switch is coupled between the first portion of the second power delivery network and the first power delivery network.

24. The IC package of claim 21, further comprising:
a package substrate;
wherein the conductive contacts at the face of the first die are first conductive contacts, the face of the first die is a first face, the first die further includes second conductive contacts at a second face of the first die, the second face of the first die is opposite to the first face of the first die; and the second conductive contacts at the second face of the first die are coupled to conductive contacts at a face of the package substrate.

25. The IC package of claim 21, wherein the second die includes a processing core.
